(19) United States
(12) Patent Application Publication
(10) Pub. No.: US 2023/0416916 A1
(43) Pub. Date: Dec. 28, 2023

(54) SUBSTRATE PROCESSING APPARATUS, METHOD OF MANUFACTURING SEMICONDUCTOR DEVICE, AND RECORDING MEDIUM

(71) Applicant: Kokusai Electric Corporation, Tokyo (JP)

(72) Inventor: Hidehiro YANAI, Toyama-shi (JP)

(73) Assignee: Kokusai Electric Corporation, Tokyo (JP)

(21) Appl. No.: 18/336,524

(22) Filed: Jun. 16, 2023

(30) Foreign Application Priority Data
Jun. 28, 2022 (JP) 2022-103864

(51) Int. Cl. C23C 16/455; C23C 16/52; C23C 16/34

(52) U.S. Cl. CPC C23C 16/45561; H01L 21/02186; C23C 16/34; C23C 16/52

(57) ABSTRACT

A technique includes a process container configured to process a substrate, a storage container which is at least partially in contact with an outer wall of the process container and is configured to store a gas to be supplied into the process container, and a temperature regulator configured to regulate an internal temperature of the storage container.

### CROSS-REFERENCE TO RELATED APPLICATION

This application is based upon and claims the benefit of priority from Japanese Patent Application No. 2022-103864, filed on Jun. 28, 2022, the entire contents of which are incorporated herein by reference.

### TECHNICAL FIELD

The present disclosure relates to a substrate processing apparatus, a method of manufacturing a semiconductor device, and a recording medium.

### BACKGROUND

When forming a film on a semiconductor substrate, there is a case where a batch-type substrate processing apparatus is used, in which a tank installed at a gas supply pipe is filled with a gas, and then, the gas charged inside the tank is supplied into a process chamber.

### SUMMARY

In a single-wafer-type substrate processing apparatus, it may be anticipated to process a substrate having a high aspect ratio structure using tanks that supply a large amount of gas at once into a process container, in order to improve coverage performance. Further, in order to warm these tanks uniformly, a heating device that heats each tank is required, which leads to a need for energy saving.

Some embodiments of the present disclosure provide a technique capable of improving characteristics of a film formed on a substrate while achieving energy saving by using heat in a process container.

According to one embodiment of the present disclosure, there is provided a technique that includes: a process container configured to process a substrate; a storage container which is at least partially in contact with an outer wall of the process container and is configured to store a gas to be supplied into the process container; and a temperature regulator configured to regulate an internal temperature of the storage container.

### BRIEF DESCRIPTION OF DRAWINGS

The accompanying drawings, which are incorporated in and constitute a part of the specification, illustrate embodiments of the present disclosure.

FIG. 1 is a diagram of a schematic configuration of a substrate processing apparatus suitably used in embodiments of the present disclosure and illustrates a process furnace section in a longitudinal cross-sectional view.

FIG. 2 is a diagram of a schematic configuration of a controller of the substrate processing apparatus suitably used in embodiments of the present disclosure and illustrates a control system of the controller in a block diagram.

FIG. 3 is a diagram illustrating a substrate processing sequence suitably used in embodiments of the present disclosure.

FIG. 4 is a diagram illustrating a modification of the substrate processing sequence suitably used in embodiments of the present disclosure.

FIG. 5 is a diagram illustrating a modification of the substrate processing sequence suitably used in embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, one embodiment of the present disclosure will be described with reference to the accompanying drawings. In addition, the drawings used in the following description are all schematic, and a dimensional relationship of each element, the ratio of each element, and the like illustrated in the drawings do not essentially match with those in reality. Further, even between a plurality of drawings, a dimensional relationship of each element, the ratio of each element, and the like do not essentially match.

### (1) Configuration of Substrate Processing Apparatus

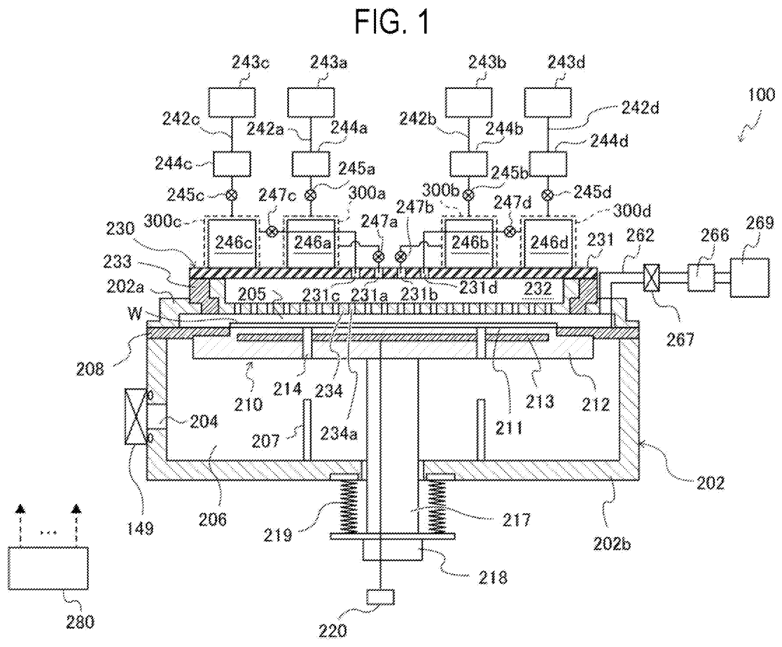

As illustrated in FIG. 1, a substrate processing apparatus 100 includes a process container 202. The process container 202 is configured as, for example, a flat hermetically-sealed container having a circular cross section. Further, the process container 202 is made of a metallic material such as, for example, aluminum (Al), stainless steel (SUS) or the like. A process space 205 in which a wafer W as a substrate is processed and a transfer space 206 through which the wafer W passes when transferring the wafer W to the process space 205 are defined in the process container 202. The process container 202 is composed of an upper container 202a and a lower container 202b. A partition plate 208 is installed between the upper container 202a and the lower container 202b.

A substrate loading/unloading port 204 that is adjacent to a gate valve 149 is installed at a side surface of the lower container 202b. The wafer W moves between a transfer chamber (not illustrated) and the lower container 202b via the substrate loading/unloading port 204. A plurality of lifting pins 207 are installed at the bottom of the lower container 202b.

A substrate support 210, which supports the wafer W, is arranged in the process space 205. The substrate support 210 includes a substrate mounting surface 211 on which the wafer W is mounted, a substrate mounting table 212 having the substrate mounting surface 211 on a surface thereof, and a heater 213 as a heat source installed in the substrate mounting table 212. The substrate mounting table 212 is provided with through-holes 214, through which the lifting pins 207 pass, at positions corresponding to the lifting pins 207, respectively. The heater 213 is connected to a heater controller 220 and is heated to a desired temperature by an instruction of a controller 280.

A shower head 230 as a gas distributor is installed at the top (i.e., upstream side) of the process space 205. A cover 231 of the shower head 230 is provided with gas introduction holes 231a to 231d. The gas introduction holes 231a to 231d communicate with gas supply pipes 242a to 242d, respectively.

The shower head 230 includes a distribution plate 234 as a distributor for distributing a gas. An upstream side of the distribution plate 234 is a buffer space 232, and the downstream side of the distribution plate 234 is the process space 205. The distribution plate 234 is provided with a plurality of through-holes 234a as gas supply ports. The distribution plate 234 is arranged to face the substrate mounting surface 211. The distribution plate 234 is configured in a disk shape, for example. The through-holes 234a are installed by being spread over the entire surface of the distribution plate 234.

The upper container 202a has a flange, and a support block 233 is mounted and fixed on the flange. The support block 233 has a flange, and the distribution plate 234 is mounted and fixed on the flange. Furthermore, the cover 231 is fixed at an upper surface of the support block 233.

### (Gas Supplier)

The first to fourth gas supply pipes 242a to 242d are connected, respectively, to the cover 231 so as to communicate with the gas introduction holes 231a to 231d formed in the cover 231 of the shower head 230.

### (First Gas Supply System)

A first gas source 243a, a mass flow controller (MFC) 244a that is a flow rate controller (flow controller), a valve 245a that is an opening/closing valve, a tank 246a as a storage container, and a valve 247a are sequentially installed at the first gas supply pipe 242a from an upstream direction thereof.

A first gas, which is a process gas and is also a precursor gas, is supplied from the first gas supply pipe 242a to the process space 205 via the MFC 244a, the valve 245a, the tank 246a, the valve 247a, the gas introduction hole 231a, the buffer space 232, and the through-holes 234a.

A first gas supply system is mainly composed of the first gas supply pipe 242a, the MFC 244a, the valve 245a, the tank 246a, and the valve 247a. In addition, the first gas source 243a may be included in the first gas supply system.

### (Second Gas Supply System)

A second gas source 243b, an MFC 244b, a valve 245b, a tank 246b, and a valve 247b are sequentially installed at the second gas supply pipe 242b from an upstream direction.

A second gas, which is a process gas and is also a reaction gas, is supplied from the second gas supply pipe 242b to the process space 205 via the MFC 244b, the valve 245b, the tank 246b, the valve 247b, the gas introduction hole 231b, the buffer space 232, and the through-holes 234a.

A second gas supply system is mainly composed of the second gas supply pipe 242b, the MFC 244b, the valve 245b, the tank 246b, and the valve 247b. In addition, the second gas source 243b may be included in the second gas supply system.

### (Third Gas Supply System)

A third gas source 243c, an MFC 244c, a valve 245c, a tank 246c, and a valve 247c are sequentially installed at the third gas supply pipe 242c from an upstream direction.

An inert gas is supplied from the third gas supply pipe 242c to the process space 205 via the MFC 244c, the valve 245c, the tank 246c, the valve 247c, the gas introduction hole 231c, the buffer space 232, and the through-holes 234a.

A third gas supply system (also referred to as an inert gas supply system) is mainly composed of the third gas supply pipe 242c, the MFC 244c, the valve 245c, the tank 246c, and the valve 247c. In addition, the third gas source 243c may be included in the third gas supply system.

### (Fourth Gas Supply System)

A fourth gas source 243d, an MFC 244d, a valve 245d, a tank 246d, and a valve 247d are sequentially installed at the fourth gas supply pipe 242d from an upstream direction.

An inert gas is supplied from the fourth gas supply pipe 242d to the process space 205 via the MFC 244d, the valve 245d, the tank 246d, the valve 247d, the gas introduction hole 231d, the buffer space 232, and the through-holes 234a.

Further, a fourth gas supply system (also referred to as an inert gas supply system) is composed of the fourth gas supply pipe 242d, the MFC 244d, the valve 245d, the tank 246d, and the valve 247d. In addition, the fourth gas source 243d may be included in the fourth gas supply system.

Further, the third gas supply system and the fourth gas supply system also act as purge gas supply systems for supplying a purge gas which purges a gas remaining in the process container 202 or in the shower head 230 in a substrate processing process.

### (Tank)

Each of the tanks 246a to 246d is configured so as to store gases to be supplied into the process space 205 before supplying them into the process space 205.

Further, the tanks 246a to 246d are mounted on an upper surface of the cover 231 of the shower head 230 that is an upper surface of the process container 202. That is, the tanks 246a to 246d is installed such that each of their lower surfaces is in contact with an outer wall of the process container 202 that is the upper surface of the process container 202. In other words, the tanks 246a to 246d are installed so as to be at least partially in contact with the outer wall of the process container 202. The tanks 246a to 246d are arranged in the vicinity of the gas introduction holes 231a to 231d that supply the gases, which reduces waste during gas supply.

Further, the tanks 246a to 246d are configured to store the gases at a second pressure, which is equal to or less than a first pressure, after the gases are supplied at the first pressure from the respective gas supply pipes 242a to 242d. As a result, acceleration of thermal decomposition due to collisions between gas molecules in storage spaces within the tanks 246a to 246d can be suppressed.

Further, the tanks 246a to 246d are installed, respectively, with tank heaters 300a to 300d which heat the interior of the tanks 246a to 246d. A temperature regulator 302 is connected to the tank heaters 300a to 300d.

The temperature regulator 302 is configured to regulate internal temperatures of the tanks 246a to 246d. For example, the temperature regulator 302 regulates each of the internal temperatures of the tanks 246a to 246d to a temperature lower than a decomposition temperature of the gases stored in each of the tanks 246a to 246d. Further, the temperature regulator 302 regulates the internal temperatures of the tanks 246a to 246d to a temperature lower than a process temperature of the wafer W. The process temperature in the present disclosure refers to a temperature of the wafer 200 or an internal temperature of the process chamber 201. This is also applied to the following descriptions.

The shower head 230 functions as a first gas supplier or a second gas supplier when supplying the first gas or the second gas into the process container 202. Further, the shower head 230 functions as an inert gas supplier when supplying the inert gas into the process container 202.

The substrate mounting table 212 is supported by a shaft 217. The shaft 217 passes through the bottom of the process container 202 and is connected to a lifter 218 outside the process container 202.

As the shaft 217 and the substrate mounting table 212 are raised and lowered by operating the lifter 218, it is possible for the substrate mounting table 212 to raise and lower the wafer W mounted on the substrate mounting surface 211. In addition, a periphery of a lower end of the shaft 217 is covered by a bellows 219, so that the interior of the process space 205 is kept airtight.

When transferring the wafer W, the substrate mounting table 212 is lowered to a position where the substrate mounting surface 211 faces the substrate loading/unloading port 204. Then, when forming a film on the wafer W, as illustrated in FIG. 1, the wafer W is raised until it reaches a predetermined position below the process space 205.

### (Exhauster)

An exhauster that exhausts an atmosphere of the process container 202 will be described. An exhaust pipe 262 is connected to the process container 202 so as to communicate with the process space 205. The exhaust pipe 262 is installed at a side of the process space 205. An auto pressure controller (APC) 266, which is a pressure controller that controls the interior of the process space 205 at a predetermined pressure, is installed at the exhaust pipe 262. The APC 266 includes a valve (not illustrated) capable of regulating an opening degree thereof, and regulates a conductance of the exhaust pipe 262 according to an instruction from the controller 280. A valve 267 is installed at the upstream side of the APC 266 in the exhaust pipe 262.

The exhaust pipe 262, the valve 267, and the APC 266 are collectively referred to as the exhauster. Furthermore, a vacuum pump 269 is installed. As illustrated, the vacuum pump 269 exhausts the atmosphere of the process space 205 via the exhaust pipe 262.

### (Controller)

The substrate processing apparatus 100 includes the controller 280 which controls an operation of each part of the substrate processing apparatus 100.

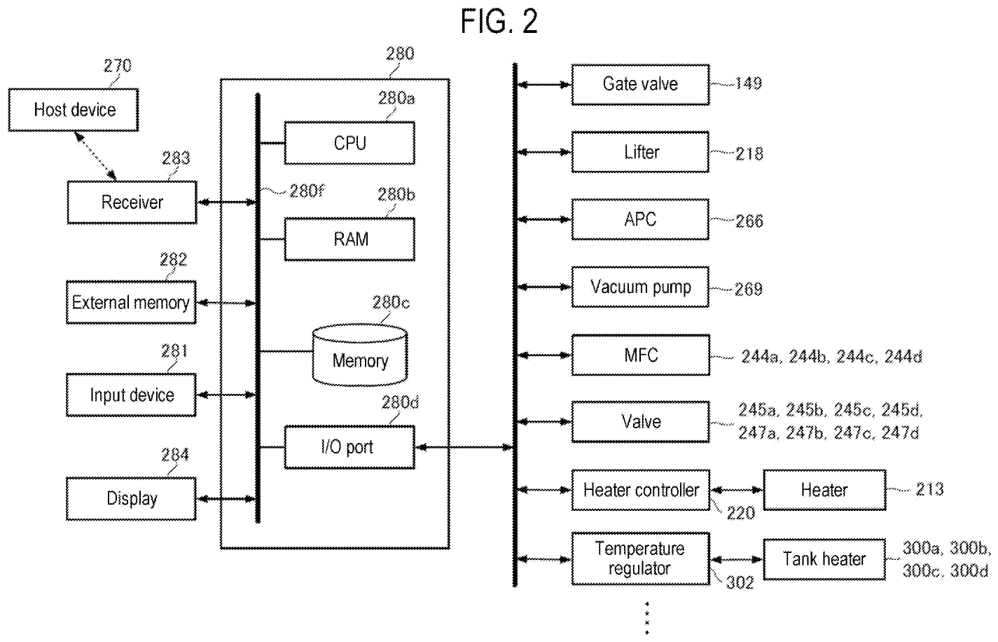

An outline of the controller 280 is illustrated in FIG. 2. The controller 280, which is a control device (control means), is configured as a computer including a central processing unit (CPU) 280a, a random access memory (RAM) 280b, a memory 280c as a memory, and an I/O port 280d. The RAM 280b, the memory 280c, and the I/O port 280d are configured to be capable of exchanging data with the CPU 280a via an internal bus 280f.

An input device 281, which is configured as, for example, a keyboard or the like, and an external memory 282 are configured to be connectable to the controller 280. Furthermore, there is installed a receiver 283 which is connected to a host device 270 via a network.

A display 284 displays data and the like which are detected by each monitor. In addition, although it has been described that the display 284 is a component different from the input device 281, the present disclosure may not be limited thereto. For example, if the input device also serves as a display screen such as a touch panel, the input device 281 and the display 284 may be integrated into one component.

The memory 280c is composed of, for example, a flash memory, a hard disk drive (HDD), and the like. In the memory 280c, a process recipe in which substrate processing procedures, conditions, and the like to be described later are written, a recipe program as a control program that controls the operation of the substrate processing apparatus for realizing the substrate processing procedures, conditions, and the like, a table to be described later, and the like are readably stored. In addition, the process recipe is a combination that causes the controller 280 to execute the respective procedures in a substrate processing process to be described later, so as to obtain predetermined results, and functions as a program. Hereinafter, the process recipe and the control program will be collectively referred to simply as a program. In addition, when the word “program” is used herein, it may include only the process recipe alone, or may include only the control program alone, or may include both. Further, the RAM 280b is configured as a memory area (work area) in which programs, data, and the like read by the CPU 280a are temporarily held.

The I/O port 280d is connected to each component of the substrate processing apparatus 100, such as the gate valve 149, the lifter 218, the APC 266, the vacuum pump 269, the MFCs 244a to 244d, the valves 245a to 245d and 247a to 247d, the heater controller 220, and the temperature regulator 302.

The CPU 280a is configured to read and execute the control program from the memory 280c and to read the process recipe from the memory 280c according to the input of an operation command or the like from the input device 281. Then, the CPU 280a is configured to, according to the contents of the process recipe thus read, be capable of controlling the opening/closing operation of the gate valve 149, the lifting operation of the lifter 218, the on/off control of the vacuum pump 269, the flow rate regulating operation of the MFCs 244a to 244d, the opening/closing operation of the valves 245a to 245d and 247a to 247d and the APC 266, the temperature control of the heater 213 by the heater controller 220, the temperature regulation of the tank heaters 300a to 300d by the temperature regulator 302, and the like.

In addition, the controller 280 according to this embodiment may be configured by, for example, installing a program to a computer using the external memory (for example, a magnetic disk such as a hard disk, an optical disk such as a DVD, a magneto-optical disk such as an MO, and a semiconductor memory such as a USB memory) 282 storing the above-described program. In addition, a way for supplying the program to the computer is not limited to the supply of the program via the external memory 282. For example, the program may be supplied using a communication facility such as the Internet or a dedicated line without the external memory 282. In addition, the memory 280c or the external memory 282 is configured as a computer-readable recording medium. Hereinafter, these are collectively referred to simply as a recording medium. In addition, when the word “recording medium” is used herein, it may include only the memory 280c alone, or may include only the external memory 282 alone, or may include both. An example of a substrate processing sequence in which a semiconductor film is formed by the above-described substrate processing apparatus on an insulating film provided on the surface of a wafer 200 as a substrate will be described as one process of manufacturing a semiconductor device mainly with reference to FIG. 4.

### (2) Substrate Processing Process

Next, an example of a method of performing a processing in which a thin film is formed on the wafer W using the substrate processing apparatus 100 as one process of manufacturing a semiconductor device will be described. In addition, in the following description, the operation of each part constituting the substrate processing apparatus 100 is controlled by the controller 280.

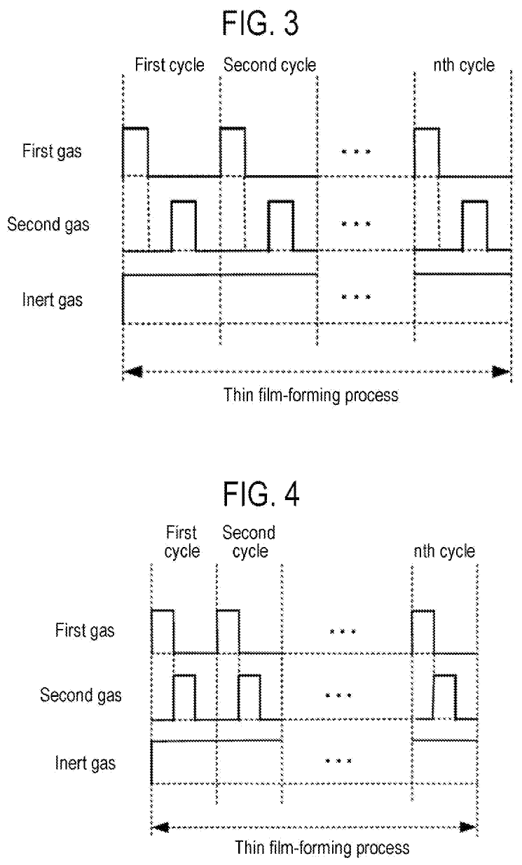

Hereinafter, a substrate processing process of this embodiment will be specifically described with reference to FIG. 3.

In addition, when the term “wafer” is used herein, it may refer to “a wafer itself”, or may refer to “a stacked (assembly) of a wafer and a predetermined layer, film or the like formed on a surface thereof” (that is, a wafer including a predetermined layer, film or the like formed on a surface thereof may be called the wafer). Further, when the word “a surface of the wafer” is used herein, it may refer to “a surface (exposed surface) of the wafer itself”, or may refer to “a surface of the predetermined layer, film or the like formed on the wafer, that is, an outermost surface of the wafer as a stack”.

Accordingly, when “a predetermined gas is supplied to the wafer” is described, it may refer to “a predetermined gas is directly supplied to the surface (exposed surface) of the wafer itself”, or may refer to “a predetermined gas is supplied to a layer, film or the like formed on the wafer, that is, to the outermost surface of the wafer as a stack”. In addition, when “a predetermined layer (or film) is formed on the wafer”, it may refer to “a predetermined layer (or film) is directly formed on the surface (exposed surface) of the wafer itself”, or may refer to “a predetermined layer (or film) is formed on a layer, film or the like formed on the wafer, that is, on the outermost surface of the wafer as a stack”.

In addition, a case of using the term “substrate” herein is the same as a case of using the word “wafer”, and in that case, it is conceivable in the above description to replace the “wafer” with the “substrate.”

### (Substrate Loading/Mounting: Step S10)

In the substrate processing apparatus 100, the substrate mounting table 212 is lowered to a transfer position of the wafer W, so that the lifting pins 207 pass through the through-holes 214 of the substrate mounting table 212. As a result, the lifting pins 207 protrude from the surface of the substrate mounting table 212 by a predetermined height. Subsequently, the gate valve 149 is opened, and by means of a wafer transporter (not illustrated), the wafer W (process substrate) is loaded into the process container 202, and the wafer W is transported onto the lifting pins 207. Thus, the wafer W is supported in a horizontal posture on the lifting pins 207 protruding from the surface of the substrate mounting table 212.

Once the wafer W has been loaded into the process container 202, the wafer transporter is withdrawn out of the process container 202, and the gate valve 149 is closed to hermetically seal the interior of the process container 202. Thereafter, the substrate mounting table 212 is raised so that the wafer W is mounted on the substrate mounting surface 211 installed at the substrate mounting table 212.

In addition, when loading the wafer W into the process chamber 202 that processes the wafer W, a N₂ gas as the inert gas may be supplied into the process container 202 from the inert gas supply system while exhausting the interior of the process container 202 by the exhaust system. That is, the inert gas may be supplied into the process container 202 by opening the valve of at least the inert gas supply system in a state where the interior of the process container 202 has been exhausted by operating the vacuum pump 269 and opening the APC 266. Thus, it is possible to prevent particles from entering the process container 202 and from adhering onto the wafer W. Further, the vacuum pump 269 is always in operation at least from substrate loading/mounting step S10 until substrate unloading step S16 to be described later is completed.

When mounting the wafer W on the substrate mounting table 212, electric power is supplied to the heater 213 embedded inside the substrate mounting table 212, and a surface of the wafer W is controlled to become a predetermined temperature. At this time, the temperature of the heater 213 is regulated by controlling the state of supplying electric power to the heater 213 by the heater controller 220 based on temperature information detected by a temperature sensor. Then, the wafer W is moved to a position illustrated in FIG. 1 by raising the substrate mounting table 212.

Further, the temperatures of the tank heaters 300a to 300d are regulated by controlling the state of supplying electric power to the tank heaters 300a to 300d by the temperature regulator 302 based on temperature information detected by temperature sensors installed at the respective tanks 246a to 246d.

At this time, the temperature regulator 302 regulates the internal temperatures of the tanks 246a to 246d to a temperature lower than the decomposition temperature of the gas stored in each tank. Thus, when the tank is filled with the gas, thermal decomposition is prevented, so that it is possible to suppress generation of particles due to thermal decomposition. Further, the temperature regulator 302 regulates the internal temperatures of the tanks 246a to 246d to a temperature lower than the process temperature of the wafer W. Thus, it is possible to suppress a decrease in the amount of active species generated by thermal decomposition during the processing of the wafer W.

Here, since lower surfaces (also referred to as bottom surfaces) of the tanks 246a to 246d are installed, respectively, in contact with the upper surface of the process container 202, a heat radiation area from the tanks 246a to 246d is reduced, and the amount of heat radiation from the tanks 246a to 246d is reduced. Further, it becomes possible to use heat in the process container 202 to heat the interior of the tanks 246a to 246d. As a result, it is possible to reduce temperature regulation for the tank heaters 300a to 300d by the temperature regulator 302, thereby promoting energy save. Here, it is desirable that an aspect ratio of each of the tanks 246a to 246d may be 1 or more, and their contact surface with the process container 202 is large. Thus, an amount of heat input from the process container 202 to the tanks 246a to 246d can be increased, and an amount of heat radiation from the tanks 246a to 246d can be reduced.

### [Thin Film-Forming Process]

### (First Gas Supply: Step S11)

Then, the first gas is flash-supplied to the wafer W in the process space 205.

Here, the flash supply refers to supplying a large amount of gas into the buffer space 232 at once. Specifically, in the flash supply, the gas is supplied in advance at a first pressure into the tank, which is installed at the gas supply pipe and is heated by the tank heater, and is then stored at a second pressure equal to or less than the first pressure. This may prevent acceleration of thermal decomposition due to collisions between gas molecules in the storage space within the tanks 246a to 246d. Then, by opening a valve installed at the downstream side of the tank when supplying the gas, a large amount of gas may be supplied at a higher speed than a case where no tank is used.

In this step, the first gas is supplied into the first gas supply pipe 242a from the tank 246a, in which the first gas is stored in advance by opening the vale 245 and regulating the flow rate of the first gas by the MFC 244a, by opening the valve 247a. After a predetermined time has passed, the valve 247a is closed to stop the supply of the first gas into the first gas supply pipe 242a. The first gas is supplied in a large amount at once from the first gas supply pipe 242a into the process space 205 via the gas introduction hole 231a, the buffer space 232, and the through-holes 234a, and is discharged from the exhaust pipe 262.

At this time, the valves 245c, 247c, 245d, and 247d may be simultaneously opened to supply a N₂ gas as the inert gas from the third gas supply pipe 242c and the fourth gas supply pipe 242d, respectively. The N₂ gas having the regulated flow rate is supplied into the process space 205 via the third gas supply pipe 242c, the fourth gas supply pipe 242d, the gas introduction holes 231c and 231d, the buffer space 232, and the through-holes 234a, and is discharged from the exhaust pipe 262.

At this time, the first gas is supplied into the process space 205 while the wafer W is supported on the substrate mounting table 212. The first gas is supplied to the wafer W.

The first gas is, for example, a metal-containing gas. For example, titanium tetrachloride (TiCl₄) gas or the like is used as the metal-containing gas.

### (Residual Gas Removal: Step S12)

Next, the inert gas is flash-supplied to the wafer W in the process space 205, and the residual gas in the process space 205 is removed.

In this step, the inert gas is supplied into the third gas supply pipe 242c and the fourth gas supply pipe 242d, respectively, from the tanks 246c and 246d, in which the inert gas is stored in advance by opening the valves 245c and 245d and regulating the flow rate of the inert gas by the MFCs 244c and 244d, by opening the valves 247c and 247d. After a predetermined time has passed, the valves 247c and 247d are closed to stop the supply of the inert gas into the third gas supply pipe 242c and the fourth gas supply pipe 242d. The inert gas is supplied in a large amount at once from the third gas supply pipe 242c and the fourth gas supply pipe 242d into the process space 205 via the gas introduction holes 231c and 231d, the buffer space 232, and the through-holes 234a, and is discharged from the exhaust pipe 262. Thus, a large amount of inert gas may be supplied at a higher speed than a case where no tank is used.

At this time, while the valve 267 of the exhaust pipe 262 and the APC 266 remain open, the interior of the process space 205 is vacuum-exhausted by the vacuum pump 269, and the first gas remaining in the process space 205, which has not reacted or has contributed to the adsorption of the first gas, and reaction by-products are removed from the process space 205 (residual gas removal). The N₂ gas acts as a purge gas, thereby enhancing the effect of excluding the first gas remaining in the process space 205, which has not reacted or has contributed to the adsorption of the first gas, and reaction by-products from the interior of the process space 205.

### (Second Gas Supply: Step S13)

Then, the second gas is flash-supplied to the wafer W in the process space 205.

In this step, the second gas is supplied into the second gas supply pipe 242b from the tank 246b, in which the second gas is stored in advance by opening the valve 245b and regulating the flow rate of the second gas by the MFC 244b, by opening the valve 247b. After a predetermined time has passed, the valve 247b is closed to stop the supply of the second gas into the second gas supply pipe 242b. The second gas is supplied in a large amount at once from the second gas supply pipe 242b into the process space 205 via the gas introduction hole 231b, the buffer space 232, and the through-holes 234a, and is discharged from the exhaust pipe 262.

At this time, the valves 245c, 247c, 245d, and 247d may be simultaneously opened to supply a N₂ gas as the inert gas from the third gas supply pipe 242c and the fourth gas supply pipe 242d, respectively. The N₂ gas having the regulated flow rate is supplied into the process space 205 via the third gas supply pipe 242c, the fourth gas supply pipe 242d, the gas introduction holes 231c and 231d, the buffer space 232, and the through-holes 234a, and is discharged from the exhaust pipe 262.

At this time, the second gas is supplied into the process space 205 while the wafer W is supported on the substrate mounting table 212. The second gas is supplied to the wafer W.

The second gas is a gas different from the first gas and reacts with the first gas. Here, the second gas is described as a nitrogen (N)-containing gas, for example. Specifically, an ammonia (NH₃) gas is used as the N-containing gas. The first gas and the second gas react to each other and form a titanium nitride (TiN) film on the wafer W.

### (Residual Gas Removal: Step S14)

Then, the inert gas is flash-supplied to the wafer W in the process space 205, and the residual gas in the process space 205 is removed.

In this step, the inert gas is supplied into the third gas supply pipe 242c and the fourth gas supply pipe 242d, respectively, from the tanks 246c and 246d, in which the inert gas is stored in advance by opening the valves 245c and 245d and regulating the flow rate of the inert gas by the MFCs 244c and 244d, by opening the valves 247c and 247d. After a predetermined time has passed, the valves 247c and 247d are closed to stop the supply of the inert gas into the third gas supply pipe 242c and the fourth gas supply pipe 242d. The inert gas is supplied in a large amount at once from the third gas supply pipe 242c and the fourth gas supply pipe 242d into the process space 205 via the gas introduction holes 231c and 231d, the buffer space 232, and the through-holes 234a, and is discharged from the exhaust pipe 262.

At this time, while the valve 267 of the exhaust pipe 262 and the APC 266 remain open, the interior of the process space 205 is vacuum-exhausted by the vacuum pump 269, and the second gas remaining in the process space 205, which has not reacted or has contributed to the adsorption of the second gas, and reaction by-products are removed from the process space 205 (residual gas removal). The N₂ gas acts as a purge gas, thereby enhancing the effect of excluding the second gas remaining in the process space 205, which has not reacted or has contributed to the adsorption of the second gas, and reaction by-products from the process space 205.

### (Performing a Predetermined Number of Times: Step S15)

A cycle of performing the above-described steps S11 to S14 is performed a predetermined number of times (n times, where n is an integer greater than or equal to 1), whereby a thin film having a desired film thickness is formed on the wafer W.

### (Substrate Unloading: Step S16)

Next, the substrate mounting table 212 is lowered, and the wafer W is supported on the lifting pins 207 protruding from the surface of the substrate mounting table 212. Thereafter, the gate valve 149 is opened, and the wafer W is unloaded out of the process container 202 using the wafer transporter. Thereafter, when completing the substrate processing process, the supply of the inert gas from the inert gas supply system into the process container 202 is stopped.

That is, heat in the process space 205 may be used to heat the tanks 246a to 246d, which leads to a reduction in the amount of electric power required for heating, resulting in energy saving. Further, using the tanks 246a to 246d may improve film characteristics such as the coverage performance of the film formed on the wafer W.

### (3) Modifications

A substrate processing sequence in the above-described embodiment may be modified as in modifications illustrated below. In the following, unless otherwise specified, configurations in the modifications are the same as that in the above-described embodiment, and the description thereof will be omitted.

### Modification 1

FIG. 4 is a diagram illustrating a substrate processing sequence according to Modification 1.

In this modification, step S12 in the substrate processing process of the above-described embodiment is not performed on the wafer W. That is, the flash supply of the first gas (S11) and the flash supply of the second gas (S13) are successively performed on the wafer W, and thereafter, the residual gas removal (S14) is performed. This modification also obtains the same effects as in the above-mentioned embodiment. Further, this modification may also shorten the process time and improve the throughput, compared to the substrate processing process of the above-described embodiment. The process time herein means the time during which the processing is continued. This is also applied to the following description.

### Modification 2

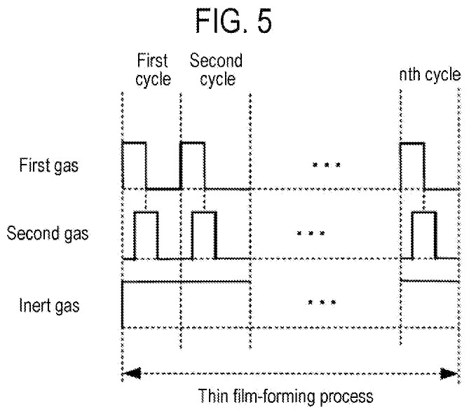

FIG. 5 is a diagram illustrating a substrate processing sequence according to Modification 2.

In this modification, the flash supply of the first gas (S11) to the wafer W starts, and before the flash supply of the first gas is stopped, the flash supply of the second gas (S13) starts. Then, after the flash supply of the second gas (S13) starts, the flash supply of the first gas is stopped, and after the flash supply of the first gas is stopped, the flash supply of the second gas is stopped. That is, the flash supply of the first gas (S11) and the flash supply of the second gas (S13) are performed so as to partially overlap with each other. This modification also obtains the same effects as in the above-mentioned embodiment. Further, this modification may also further shorten the process time and improve the throughput, compared to the substrate processing process of the above-described embodiment and Modification 1.

The embodiment and modifications of the present disclosure have been specifically described above. However, the present disclosure is not limited to the above-described embodiment and modifications, and may be changed in various ways without departing from the gist of the present disclosure.

For example, the above-described embodiment has been described using the configuration in which various gases are stored in the tanks 246a to 246d and are flash-supplied to the wafer W in the process space 205, but the present disclosure is not limited thereto. At least one selected from the group of the first gas and the second gas may be stored in a tank and may be flash-supplied, or the inert gas may be supplied into the process space 205 without using the tank. This embodiment also obtains the same effects as in the above-described aspect.

Further, the above embodiment has been described using the case where the tank heaters 300a to 300d are installed at the respective tanks 246a to 246d and these tank heaters 300a to 300d are regulated by the temperature regulator 302, but the present disclosure is not limited thereto, and a tank having the temperature regulator may be used. This embodiment also obtains the same effects as in the above-described embodiment.

In addition, the gas in the above embodiment is not limited to the gas types described above. Further, the case of forming the thin film using the first gas and the second gas has been described as a thin film-forming process by way of example, but the present disclosure is not limited thereto, and one gas or three or more gases may be used. This embodiment also obtains the same effects as in the above-described embodiment.

Further, the above embodiment has been described using the case where the first to fourth gas supply systems are connected to the cover 231, respectively, and each gas is supplied into the process space 205 from each gas supply pipe, but the present disclosure is not limited thereto. The first gas supply system to the fourth gas supply system may be connected to one gas supply pipe, and each gas may be supplied into the process space 205 by one gas supply pipe. This embodiment also obtains the same effects as in the above-described embodiment.

Further, recipes used for a substrate processing may be individually prepared according to the content of processing and may be stored in the memory 280c via an electric communication line or the external memory 282. Then, when starting the substrate processing, the CPU 280a may appropriately select an appropriate recipe among a plurality of recipes stored in the memory 280c according to the content of the substrate processing. Thus, a single substrate processing apparatus may form films having various film types, composition ratios, film qualities, and film thicknesses with good reproducibility. Further, the operator's burden may be reduced, and the processing may be started quickly while avoiding operational errors.

The above-described recipe is not limited to a case of newly creating the recipe, but may be prepared by changing an existing recipe that has already been installed in the substrate processing apparatus, for example. When changing the recipe, the changed recipe may be installed in the substrate processing apparatus via an electric communication line or a recording medium on which that recipe is recorded. Further, the existing recipe that has already been installed in the substrate processing apparatus may be directly changed by operating the input device 281 installed in the existing substrate processing apparatus.

The above-described embodiment has described an example of forming a film using a single-wafer-type substrate processing apparatus that processes one or several substrates at a time. The present disclosure is not limited to the above-described embodiment, and may be suitably applied, for example, even when a film is formed using a batch-type substrate processing apparatus that processes a plurality of substrates at once. Further, the above-described embodiment has described an example of forming a film using a substrate processing apparatus having a cold-wall-type process furnace. The present disclosure is not limited to the above-described embodiment, and may be suitably applied even when a film is formed using a substrate processing apparatus having a hot-wall-type process furnace.

Even when these substrate processing apparatuses are used, a substrate processing may be performed under the same processing procedures and processing conditions as in the above-described embodiment and modifications and similar effects may be obtained.

According to the present disclosure in some embodiments, it is possible to improve characteristics of a film formed on a substrate while achieving energy saving by using heat in a process container.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a process container configured to process a substrate;
a storage container which is at least partially in contact with an outer wall of the process container and is configured to store a gas to be supplied into the process container; and
a temperature regulator configured to regulate an internal temperature of the storage container.

2. The substrate processing apparatus of claim 1, wherein the temperature regulator is configured to be capable of regulating the internal temperature of the storage container to a temperature lower than a decomposition temperature of the gas stored in the storage container.

3. The substrate processing apparatus of claim 1, wherein the temperature regulator is configured to be capable of regulating the internal temperature of the storage container to a temperature lower than a process temperature of the substrate.

4. The substrate processing apparatus of claim 1, wherein the gas is supplied to the storage container at a first pressure, and then the gas is stored at a second pressure equal to or less than the first pressure.

5. The substrate processing apparatus of claim 1, wherein an inert gas is stored in another storage container.

6. The substrate processing apparatus of claim 1, wherein a first gas is supplied into the process container, and then a second gas different from the first gas is supplied into the process container.

7. The substrate processing apparatus of claim 6, wherein at least one selected from the group of the first gas and the second gas is stored in the storage container.

8. A method of manufacturing a semiconductor device, comprising:
storing a gas in a storage container which is at least partially in contact with an outer wall of a process container configured to process a substrate, wherein an internal temperature of the storage container is regulated by a temperature regulator; and
supplying the gas, which is stored in the storage container, into the process container.

9. The method of claim 8, wherein, in the act of storing the gas, the internal temperature of the storage container is regulated to a temperature lower than a decomposition temperature of the gas stored in the storage container by the temperature regulator.

10. The method of claim 8, wherein the temperature regulator is configured to be capable of regulating the internal temperature of the storage container to a temperature lower than a process temperature of the substrate.

11. The method of claim 8, further comprising supplying the gas into the storage container at a first pressure,
wherein, in the act of storing the gas, the gas is supplied into the storage container at the first pressure, and then the gas is stored in the storage container at a second pressure equal to or less than the first pressure.

12. The method of claim 8, further comprising storing an inert gas in another storage container.

13. The method of claim 8, further comprising supplying a first gas into the process container, and thereafter, supplying a second gas different from the first gas.

14. The method of claim 13, wherein in the act of storing the gas, at least one selected from the group of the first gas and the second gas is stored in the storage container.

15. A non-transitory computer-readable recording medium storing a program that causes, by a computer, a substrate processing apparatus to perform a process comprising:
storing a gas in a storage container which is at least partially in contact with an outer wall of a process container configured to process a substrate, wherein an internal temperature of the storage container is regulated by a temperature regulator, and
supplying the gas, which is stored in the storage container, into the process container.

16. The non-transitory computer-readable recording medium of claim 15, wherein, in the act of storing the gas, the internal temperature of the storage container is regulated to a temperature lower than a decomposition temperature of the gas stored in the storage container by the temperature regulator.

17. The non-transitory computer-readable recording medium of claim 15, wherein the process further comprises supplying the gas into the storage container at a first pressure,
wherein, in the act of storing the gas, the gas is supplied into the storage container at the first pressure, and then the gas is stored in the storage container at a second pressure equal to or less than the first pressure.

18. The non-transitory computer-readable recording medium of claim 15, wherein the process further comprises storing an inert gas in the storage container.

19. The non-transitory computer-readable recording medium of claim 15, wherein the process further comprises supplying a first gas into the process container, and thereafter, supplying a second gas different from the first gas.

20. The non-transitory computer-readable recording medium of claim 19, wherein, in the storing the gas, at least one selected from the group of the first gas and the second gas is stored in the storage container.
